(19) United States
(12) Patent Application Publication
(10) Pub. No.: US 2025/0305121 A1
(43) Pub. Date: Oct. 2, 2025

(54) Biomimetic Physical Antimicrobial Polymer Foils

(71) Applicant: The Board of Trustees of the University of Illinois, Urbana, IL (US)

(72) Inventors: Qing Cao, Champaign, IL (US); Yi Zhang, Champaign, IL (US); Hsien-Nung Wang, Urbana, IL (US)

(21) Appl. No.: 19/097,453

(22) Filed: Apr. 1, 2025

Related U.S. Application Data
(60) Provisional application No. 63/572,500, filed on Apr. 1, 2024.

(51) Int. Cl. C23C 16/40; C23C 16/50; C23C 16/52; C23C 16/56

(52) U.S. Cl. CPC C23C 16/402; C23C 16/50; C23C 16/52; C23C 16/56

(57) ABSTRACT

Methods of and apparatuses for the manufacture of biomimetic physical antimicrobial polymer foils are disclosed. An example method of manufacturing includes providing a substrate. The method additionally includes depositing an aluminum-containing layer on the substrate. The method yet further includes anodizing an exposed surface of the aluminum-containing layer in a first bath so as to form a plurality of pores in the exposed surface of the aluminum-containing layer. Moreover, the method includes immersing the exposed surface of the aluminum-containing layer in a second bath, further etching the plurality of pores in the exposed surface of the aluminum-containing layer. Methods also include formation of templated polypropylene and cellulose films.

### CROSS-REFERENCE TO RELATED APPLICATION

The present application claims the benefit of U.S. Provisional Patent Application No. 63/572,500, filed Apr. 1, 2024, the content of which is herewith incorporated by reference.

### STATEMENT REGARDING FEDERALLY SPONSORED RESEARCH OR DEVELOPMENT

This invention was made with government support under 2015292 awarded by the National Science Foundation and W81XWH2110290 awarded by the Department of Defense. The government has certain rights in the invention.

### BACKGROUND

Biofouling, the accumulation of unwanted biological matter on surfaces, is a critical problem in a wide range of medical, food, marine, construction, and industrial applications. For example, between 4% and 10% of patients in hospitals contract hospital-acquired infections, resulting in nearly 99,000 and 33,000 annual deaths in United States and European Union, respectively. Meanwhile, about one-third of the food produced globally is lost or wasted each year, largely resulting from food deterioration and spoilage caused by bacteria. A potential solution is the creation of antimicrobial surfaces, capable of inhibiting the growth of pathogens. Conventional strategies to produce antimicrobial surfaces include coating the surface with hydrophobic or hydrophilic molecules to obstruct bacterial adhesion and coating the surface with antimicrobial agents. However, coating a surface with hydrophilic molecules to obstruct bacterial adhesion may still result in some bacterial adhesion, potentially leading to the development of an antibiotic-resistant biofilm. Further, a surface with antimicrobial agents, such as silver, copper, or antibiotics, loses efficacy over time and risks environmental contamination, antibiotic resistance, hot-tissue toxicity, and acute inflammatory responses.

Certain natural surfaces exhibit bactericidal functionality. For example, cicada wings contain regular arrays of nanopillars with 50-100 nm diameter, around 200 nm pitch, and around 200-400 nm height. These arrays of nanopillars possess a high bactericidal efficacy through mechanically rupturing the membranes of cells that come into contact with the arrays. In addition, such arrays are safe for contact with human skin. However, the reproduction of such high density, submicron, and high-aspect-ratio structures on large films or foils capable of being applied to large areas poses fabrication challenges. Though small films may be sufficient in limited situations, for example, to cover some high-value biomedical implants, these fabrication challenges hinder broad adoption of such films.

### SUMMARY

The embodiments described herein provide methods of and apparatuses for the manufacture of biomimetic physical antimicrobial polymer foils to provide non-toxic bacteria-killing surfaces.

In a first aspect, a method is provided. The method may include providing a substrate. The method may also include depositing an aluminum-containing layer on the substrate. The method may further include anodizing an exposed surface of the aluminum-containing layer in a first bath so as to form a plurality of pores in the exposed surface of the aluminum-containing layer. Moreover, the method may include immersing the exposed surface of the aluminum-containing layer in a second bath, further etching the plurality of pores in the exposed surface of the aluminum-containing layer.

In a second aspect, an apparatus is provided. The apparatus may include an aluminum-containing deposition system, wherein the aluminum-containing deposition system is configured to deposit an aluminum-containing layer on a substrate. The apparatus may also include a first bath, wherein the first bath is configured to anodically etch a plurality of pores in an exposed surface of the aluminum-containing layer. The apparatus may further include a second bath, wherein the second bath is configured to further etch the plurality of pores.

In a third aspect, a further method is provided. The method may include applying an adhesion layer to a substrate, wherein the adhesion layer comprises 1 nanometer thick titanium, wherein the substrate comprises silicon or glass. The method may also include depositing an aluminum-containing layer on the adhesion layer, wherein the aluminum-containing layer comprises a thickness of 150-400 nanometers, and wherein depositing the aluminum-containing layer is performed with a metal sputtering deposition process. The method may further include anodizing an exposed surface of the aluminum-containing layer in a first bath so as to form a plurality of pores in the exposed surface of the aluminum-containing layer, wherein the first bath comprises a 5% by volume phosphoric acid solution, and wherein the anodizing comprises applying a voltage of approximately 175 volts and stirring the first bath at approximately 300 rotations per minute. Moreover, the method may include immersing the exposed surface of the aluminum-containing layer in a second bath, further etching the plurality of pores in the exposed surface of the aluminum-containing layer, wherein the pores have diameters of approximately 100-150 nanometers, pitches between 200 and 300 nanometers, and depths of between 300 and 800 nanometers, and wherein the second bath comprises a 10% by volume phosphoric acid solution.

In addition, the method may include cleaning the exposed surface of the aluminum-containing layer. Further, the method may include depositing a hydrophobicity-modifying layer on the exposed surface of the aluminum-containing layer, wherein depositing the hydrophobicity-modifying layer comprises exposing the exposed surface of the aluminum-containing layer to trichlorosilane vapor in a desiccator or exposing the exposure surface of the aluminum layer to oxygen plasma. The method may also include depositing a polymer layer on the hydrophobicity-modifying layer, wherein the polymer layer comprises polypropylene (PP). The method may further include heating the aluminum-containing layer and the polymer layer together to a temperature of approximately 200 degrees Celsius. Moreover, the method may include, while heating the aluminum-containing layer and the polymer layer, pressing the polymer layer onto the aluminum-containing layer, so as to cause a portion of the polymer layer to conformally fill the plurality of pores in the aluminum-containing layer. Additionally, the method may include separating the polymer layer from the aluminum-containing layer. Alternatively, the method may include depositing a polymer layer on the hydrophobicity-modifying layer, where the polymer layer comprises cellulose dispersed in solvent. The method may further include applying vacuum to promote the dispersed cellulose to fill the plurality of pores in the aluminum-containing layer. Additionally, the cellulose film may be solidified via solvent removal followed by separating the polymer layer from the aluminum-containing layer.

These, as well as other embodiments, aspects, advantages, and alternatives, will become apparent to those of ordinary skill in the art by reading the following detailed description, with reference where appropriate to the accompanying drawings. Further, this summary and other descriptions and figures provided herein are intended to illustrate embodiments by way of example only and, as such, that numerous variations are possible. For instance, structural elements and process steps can be rearranged, combined, distributed, eliminated, or otherwise changed, while remaining within the scope of the embodiments as claimed.

### BRIEF DESCRIPTION OF THE DRAWINGS

Example embodiments should become apparent from the following description, which is given by way of example only, of at least one preferred but non-limiting embodiment, described in connection with the accompanying figures.

FIG. 1A illustrates nanostructured cicada wings with physical bactericidal capability.

FIG. 1B illustrates a physical bactericidal mechanism.

FIG. 2 illustrates a biomimetic physical antimicrobial polymer foil and an apparatus for making the biomimetic physical antimicrobial polymer foil, according to an example embodiment.

FIG. 3 illustrates optical images of the skin tissues around planar control and the biomimetic physical antimicrobial polymer foil inoculated with P. aeruginosa and normalized counts of S. aureus and P. aeruginosa, according to an example embodiment.

FIG. 4A illustrates scanning electron microscope (SEM) images of (a) cross-sectional and (b) top views of templates to create biomimetic physical antimicrobial polymer foils, according to an example embodiment.

FIG. 4B illustrates a diagram of a template to create biomimetic physical antimicrobial polymer foils, according to an example embodiment.

FIG. 5A illustrates a SEM image of a biomimetic physical antimicrobial polymer foil after washing, according to an example embodiment.

FIG. 5B illustrates a SEM image of a biomimetic physical antimicrobial polymer foil after pressing with a finger, according to an example embodiment.

FIG. 6 illustrates a diagram of a method of manufacturing biomimetic physical antimicrobial polymer foils, according to an example embodiment.

FIG. 7 illustrates an example template used to create biomimetic physical antimicrobial polymer foils, according to an example embodiment.

FIG. 8 illustrates SEM images of an example template used to create biomimetic physical antimicrobial polymer foils, according to an example embodiment.

FIG. 9 illustrates cross-sectional view SEM images of a template used to create biomimetic physical antimicrobial polymer foils, according to an example embodiment.

FIG. 10 illustrates top-view SEM images of the biomimetic physical antimicrobial polymer foils, according to an example embodiment.

FIG. 11 illustrates part of an apparatus used to make the biomimetic physical antimicrobial polymer foils, according to an example embodiment.

FIG. 12 illustrates top-view SEM images of templates used to create biomimetic physical antimicrobial polymer foils produced at different anodization voltages and resultant pitches and pore diameters, according to an example embodiment.

FIG. 13 illustrates top-view SEM images of templates used to create biomimetic physical antimicrobial polymer foils produced at different etching times and resultant pore diameters, according to an example embodiment.

FIG. 14 illustrates a heat map of the bactericidal efficacy of the biomimetic physical antimicrobial polymer foil, according to an example embodiment.

FIG. 15 illustrates a method, according to an example embodiment.

FIG. 16 illustrates a method, according to an example embodiment.

FIG. 17 illustrates various views of a template, according to an example embodiment.

FIG. 18 illustrates various chemical structures, according to an example embodiment.

FIG. 19 illustrates various views of a cellulose film, according to an example embodiment.

The patent or application file contains at least one drawing executed in color. Copies of this patent or patent application publication with color drawings will be provided by the Office upon request and payment of the necessary fee.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features unless stated as such. Thus, other embodiments can be utilized and other changes can be made without departing from the scope of the subject matter presented herein.

Accordingly, the example embodiments described herein are not meant to be limiting. It will be readily understood that the aspects of the present disclosure, as generally described herein, and illustrated in the figures, can be arranged, substituted, combined, separated, and designed in a wide variety of different configurations.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order.

### I. Overview

The embodiments described herein provide methods of and apparatuses for the manufacture of biomimetic physical antimicrobial polymer foils to provide a non-toxic bacteria-killing surface. Certain embodiments enable the creation of large foils capable of effectively killing attached bacteria through rupturing their cell membranes in a purely mechanical stretching process. This can facilitate widespread creation and use of such foils, offering a cost-effective, “chemical-free” and wide-spectrum strategy to prevent bacteria-related infections and fouling.

In various embodiments, present disclosure describes processes for producing biomimetic physical antimicrobial polymer foils. These foils could be produced according to a master template. The master template could be formed from a substrate onto which an aluminum-containing layer is deposited. An exposed surface of this aluminum-containing layer could be anodized in a first bath, producing an anodic aluminum oxide layer containing a plurality of pores. These pores may be further etched through immersion of the exposed surface of the aluminum-containing layer in a second bath. There are multiple advantages to using anodic aluminum oxide as a basis of such a template. First, the area cost of aluminum foils is orders of magnitude lower than comparable materials, such as, single-crystalline silicon wafers. Second, the mechanical flexibility of the aluminum foils makes them more compatible with existing manufacturing processes, such as the cast foil extrusion or solvent casting manufacturing process.

In some examples, the present disclosure describes an apparatus for fabricating biomimetic physical antimicrobial polymer foils. Embodiments of the present disclosure include a cost-effective way to make biomimetic physical antimicrobial polymer foils with precisely-controlled submicron features over large area. Embodiments of the present disclosure can be used to reduce bacteria growth on the surfaces, such as food packaging, thereby increasing shelf life while maintaining food quality. Further, embodiments of the present invention can be used to protect public surfaces or filters in heating, ventilation, and air conditioning (HVAC) systems, and reduce nosocomial (hospital-acquired) infections for patients. Moreover, in embodiments where the biomimetic physical antimicrobial polymer foils are transparent, the foils can be applied to touchscreens such as smartphones.

As used herein, “about” and “approximately” mean within a statistically meaningful range of a value or values such as a stated concentration, length, width, height, pitch, depth, molecular weight, pH, sequence identity, time frame, temperature, or volume. Such a value or range can be within an order of magnitude, typically within 20%, more typically within 10%, and even more typically within 5% of a given value or range. The allowable variation encompassed by “about” or “approximately” will depend upon the particular system under study, and can be readily appreciated by one of skill in the art.

All of the patents, patent applications, patent application publications and other publications recited herein are hereby incorporated by reference as if set forth in their entirety.

The present invention has been described in connection with what are presently considered to be the most practical and preferred embodiments. However, the invention has been presented by way of illustration and is not intended to be limited to the disclosed embodiments. Accordingly, one of skill in the art will realize that the invention is intended to encompass all modifications and alternative arrangements within the scope of the invention as set forth in the claims.

### II. Example Nanostructured Thin Films

“Biomimicry”, which combines the words “bios” (life) and “mimesis” (to imitate), is a relatively new scientific field focused on the study of nature's ability to adapt to a diverse range of environmental conditions. One of the results of biomimicry has been the realization of nanoengineered surfaces (NES) that replicate nature's adaptation to: attract or repel various liquids, adhere to or release from surfaces in wet or dry conditions, endure wear, resist hostile corrosive environments, manage heat transfer, and/or manage incident light.

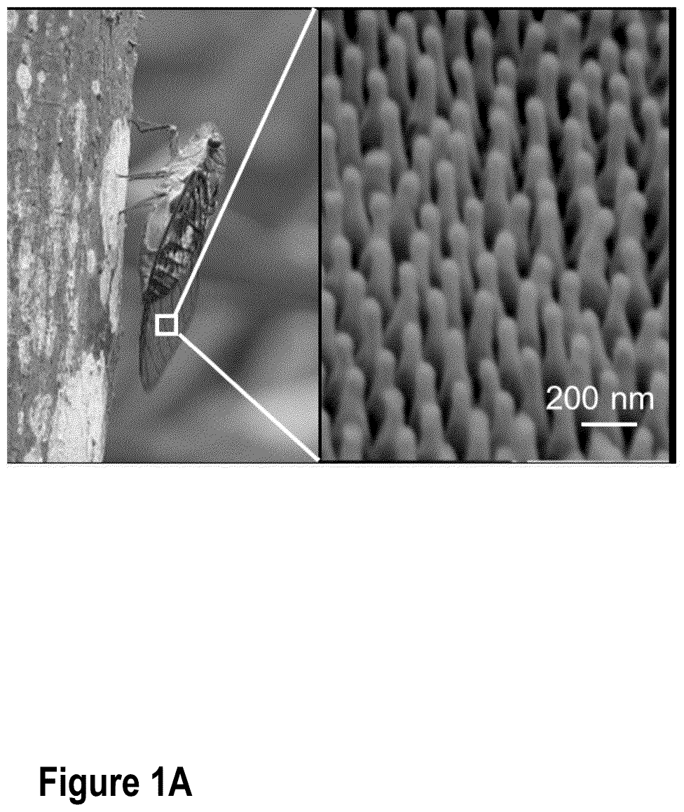

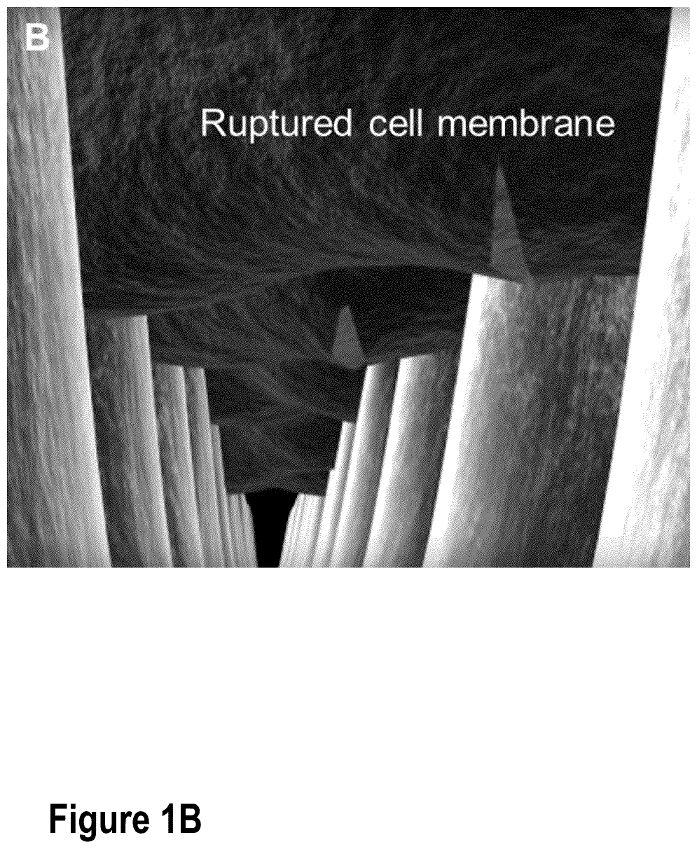

For example, the wings of the cicada exhibit regular arrays of nanopillars that have high bactericidal efficacy by mechanically rupturing the membranes of cells that attach to wing surfaces. FIG. 1A illustrates nanostructured cicada wings with physical bactericidal capability. Arrays of nanopillars with 50-100 nm diameter, around 200 nm pitch, and 200-400 nm height cover the surfaces of cicada wings. These arrays enable the wings capable of killing attached bacteria through purely physical interactions without the release of chemicals.

FIG. 1B illustrates a possible related physical bactericidal mechanism. It is speculated that when bacteria contact the nanopillar arrays, regions of the microorganisms are suspended between the pillars because bacteria are typically 5-50 times larger than the pillar pitch. Stretching occurs in these suspended regions, rupturing cell membranes of bacteria and causing cell necrosis. This property may motivate reproductions of this naturally-occurring surface.

As one example, the biomimetic physical antimicrobial polymer foils produced by the methods of and apparatuses for the manufacture described herein could be applied to surfaces of an implantable medical device to reduce infection. It will be understood that biomimetic physical antimicrobial polymer foils may be beneficially utilized in many applications, including but not limited to those in healthcare, food safety, medical research, and/or public health.

### III. Example Methods and Apparatuses

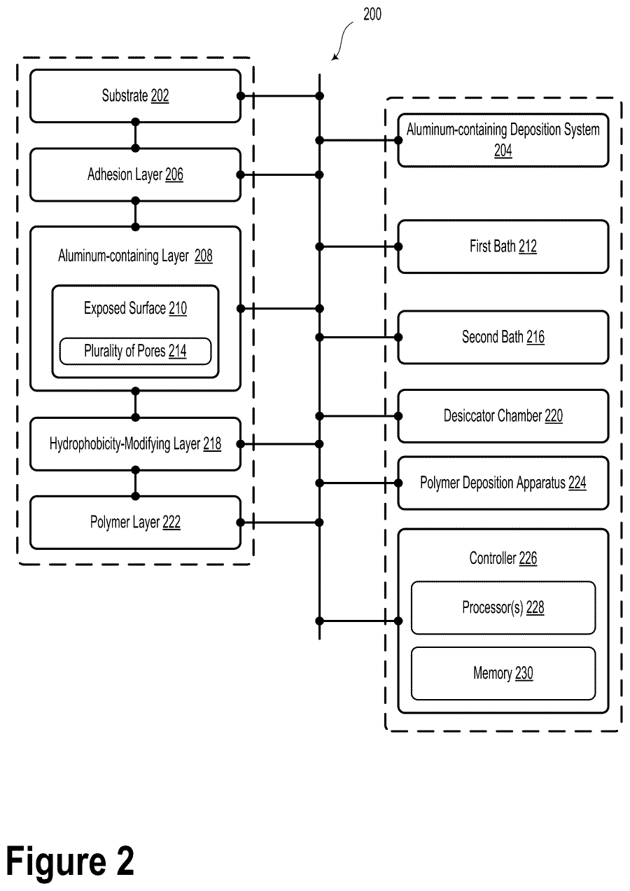

FIG. 2 illustrates a biomimetic physical antimicrobial polymer foil and an apparatus for making the biomimetic physical antimicrobial polymer foil, according to an example embodiment. According to this example embodiment, a substrate 202 may be placed in aluminum-containing deposition system 204. An adhesion layer 206 may be deposited on the substrate 202. An aluminum-containing layer 208 may be deposited on the adhesion layer 206. The aluminum-containing layer 208 could be deposited on the substrate 202. An exposed surface 210 of the aluminum-containing layer 208 could be anodized in a first bath 212. Such anodization could produce a plurality of pores 214 in the exposed surface 210. The aluminum-containing layer 208 could be immersed in second bath 216. In some embodiments, only the exposed surface 210 of the aluminum-containing layer 208 could be immersed in the second bath 216. Additionally or alternatively, the anodization process could completely anodize the aluminum-containing layer 208, so as to form a porous oxide layer. In such scenarios, anodizing the aluminum-containing layer 208 could include pores that extend completely through the entire thickness of the aluminum-containing layer 208.

A hydrophobicity-modifying layer 218 could be applied to the exposed surface 210. This application of the hydrophobicity-modifying layer 218 could be performed either with an oxygen plasma treatment in a vacuum chamber or within a desiccator chamber 220. A polymer layer 222 could be deposited on the hydrophobicity-modifying layer 218. In some examples, the hydrophobicity-modifying layer 218 could include a coating or surface treatment applied to the exposed surface 210 to alter how it interacts with water, specifically to make it more hydrophobic (water-repellent) or less hydrophobic (more wettable, i.e., more hydrophilic). In some examples, the hydrophobicity-modifying layer 218 could be either hydrophobic or hydrophilic. In example embodiments, the composition of hydrophobicity-modifying layer 218 could be selected based on the specific material used for the polymer layer 222. The polymer layer 222 could be deposited on the aluminum-containing layer 208. The deposition of the polymer layer 222 could be performed in a polymer deposition apparatus 224. Any and all of the aluminum-containing deposition system 204, first bath 212, second bath 216, desiccator chamber 220, and polymer deposition apparatus 224 could be operationally connected to a controller 226. The controller could contain one or more processors 228 and a memory 230.

In some example embodiments, the desiccator chamber 220 is configured to deposit the hydrophobicity-modifying layer 218 on the exposed surface 210 of the aluminum-containing layer 208. In some examples, the hydrophobicity-modifying layer 218 may include hexamethyldisilazane.

In some example embodiments, the polymer deposition apparatus 224 is configured to deposit the polymer layer 222 on the hydrophobicity-modifying layer 218, heat the aluminum-containing layer 208 and the polymer layer 222, and press the polymer layer 222 onto the aluminum-containing layer 208 so as to cause a portion of the polymer layer 222 to conformally fill the plurality of pores 214 in the aluminum-containing layer 208.

In some example embodiments, the polymer layer in the form of liquid or gel phase precursors is deposited on the hydrophobicity-modifying layer. These precursors fill in the plurality of pores 214 in the aluminum-containing layer 208 and are then solidified to form a solid-state thin foil through processes including crosslinking and solvent removal.

In an example embodiment, an approximately 90 nm layer of thermal oxide, such as silicon dioxide, could serve as the substrate 202. Other thicknesses for the layer of thermal oxide are possible. In various embodiments, the substrate 202 could include glass. The substrate 202 could be cleaned by a combination of acetone, isopropanol, and deionized water. The aluminum-containing layer 208 could comprise an aluminum film with a thickness of between 150 and 400 nm. The thickness of the aluminum-containing layer 208 could determine the height of the resulting biomimetic physical antimicrobial polymer foils, with a thicker aluminum-containing layer 208 resulting in a greater height of the resulting biomimetic physical antimicrobial polymer foils. After oxidation, the thickness of the aluminum-containing layer 208 could increase to between 350 and 800 nm.

In some example embodiments, the at least one processor 228 executes program instructions stored in the memory 230 so as to carry out operations. These operations can include controlling at least one of a voltage applied to the first bath 212, a temperature of the polymer deposition apparatus 224, a rate of rotation of a stirrer in the first bath 212, a pressure within the polymer deposition apparatus 224, a force at which to press the polymer layer 222 onto the aluminum-containing layer 208, a pressure within the desiccator chamber 220, or a pressure within the aluminum-containing deposition system 204.

In some example embodiments, the first bath 212 comprises a 5% by volume phosphoric acid solution and wherein the second bath 216 comprises a 10% by volume phosphoric acid solution.

In some example embodiments, the first bath 212 and the second bath 216 comprise respective phosphoric acid solutions having a same phosphoric acid formulation by volume.

In some example embodiments, plurality of pores 214 in the exposed surface 210 of the aluminum-containing layer 208 have diameters of approximately 100-200 nanometers, pitches between 200 and 300 nanometers, and depths of between 300 and 800 nanometers.

The adhesion layer 206 could be an approximately 1 nm thick piece of titanium. The adhesion layer 206 could be deposited on the substrate 202 in a sputter chamber. The aluminum-containing layer 208 could be deposited on the substrate 202 or the adhesion layer 206 via sputtering in the sputter chamber. The first bath 212 could comprise a 5% by volume phosphoric acid (H₃PO₄) solution. A direct current (DC) voltage of approximately 175 volts could be applied to the first bath 212. The pillar pitch of the resulting biomimetic physical antimicrobial polymer foils could be affected by the voltage applied to the first bath 212. The voltage could be changed over time to fine-tune the pillar pitch of the resulting biomimetic physical antimicrobial polymer foils.

The first bath 212 could be stirred at a rate of approximately 300 rpm. A higher stirring rate can promote more uniform formation of the plurality of pores 214 in the exposed surface 210 of the aluminum-containing layer 208 because it refreshes the acid interacting with the exposed surface 210. The second bath 216 could comprise an approximately 10% by volume phosphoric acid (H₃PO₄) solution. The aluminum-containing layer 208, or only the exposed surface 210, could be immersed in the second bath for 10 minutes. The time in the first bath 212 and/or the second bath 216 can increase the pillar diameter of the resulting biomimetic physical antimicrobial polymer foils. Within a range of time from approximately 10 minutes to approximately 15 minutes, the pillar diameter of the resulting biomimetic physical antimicrobial polymer foils is approximately 100 nm. Following this, the aluminum-containing layer 208 could be referred to as an anodized aluminum oxide (AAO) template.

In an example embodiment, the pH and temperature of the first bath 212 can affect the rate of oxidation and etching of the exposed surface 210 of the aluminum-containing layer 208. For example, a lower temperature of the first bath 212 could slow the both rate of oxidation and etching. Different types of acids could change the etching rate of the exposed surface 210. A lower pH of the first bath 212 and/or the second bath 216 could increase the rate of etching of the exposed surface 210. However, in some embodiments, lowering the pH of the first bath 212 and/or the second bath 216, such with as a 20% by volume phosphoric acid solution, may result in a solution with heightened volatility.

Adding a surfactant to the first bath 212 could slow the both rate of oxidation and etching. Within the first bath 212, the generation of the pitch and diameter of the plurality of pores 214, and, therefore, the resulting pillars of the biomimetic physical antimicrobial polymer foils can be correlated. The second bath 216 can control the diameter of the plurality of pores 214 and the pillars of the resulting biomimetic physical antimicrobial polymer foils.

In example embodiments, the exposed surface 210 of the aluminum-containing layer 208 could be cleaned with oxygen plasma at approximately 18 watts and approximately 500 mtorr for approximately 10 minutes. The hydrophobicity-modifying layer 218 could be applied to the aluminum-containing layer 208 by exposing the exposed surface 210 of the aluminum-containing layer 208 to trichlorosilane vapor under vacuum in the desiccator chamber 220 for between 5-20 minutes. A longer time in the desiccator chamber 220 can result in a more uniform application of the hydrophobicity-modifying layer 218. The hydrophobicity-modifying layer 218 can reduce adhesion between the polymer layer 222 and the aluminum-containing layer 208. This could result in fewer of the resulting pillars of the biomimetic physical antimicrobial polymer foils breaking off when removing the polymer layer 222 than if the polymer layer 222 were directly deposited on the aluminum-containing layer 208. In some example embodiments, the hydrophobicity-modifying layer 218 and the aluminum-containing layer 208 could be heated to a temperature of 80 degrees Celsius for approximately 5 minutes. It will be understood that other baking times and/or temperatures are possible and contemplated.

In example embodiments, the polymer layer 222 could be heated with the aluminum-containing layer 208 in a vacuum oven at approximately 200 degrees Celsius for approximately 48 hours. The polymer layer 222 could comprise at least one of: polypropylene (PP), polyethylene (PE), polyvinyl chloride (PVC), polyurethane (PU), silicone rubber, ethylene propylene diene monomer (EPDM), thermoplastic elastomers (TPEs), thermoplastic polyurethane (TPU), polyvinylidene fluoride (PVDF), cellulose, or lignin. The polymer layer 222 could also comprise polycarbonate, polyimide, polymethylmethacrylate, polydimethylsiloxane, polybutadiene, polyisoprene, polychloroprene, polystyrene, vinyl acetate, or polytetrafluoroethylene. It will be understood that other materials are possible and contemplated.

In example embodiments, the polymer layer 222 could be separated from the aluminum-containing layer 208 by hand or roll-to-roll fabrication techniques.

The pitch of the resulting biomimetic physical antimicrobial polymer foils may be in the range of 100-500 nm. The diameters of the of the resulting biomimetic physical antimicrobial polymer foils may be in the range of 50-200 nm. The height of the resulting biomimetic physical antimicrobial polymer foils may be in the range of 200-1000 nm. It will be understood that other dimensions of the nanopillars are possible and contemplated. For example, the pitch could be approximately 220 nm and the diameter could be about 100 nm, and the height could be approximately 400 nm. Additionally or alternatively, the pitch could be about 240 nm, the diameter could be in the range of 50-100 nm, and the height could be approximately 250 nm.

The mechanical stiffness of the nanopillars can also be adjusted over a wide range through either modifying the degree of cross-link in the polymer curing process or adopting different polymer materials, from polydimethylsiloxane (modulus approximately 2.5 MPa), polyurethane (modulus 20-320 MPa), polypropylene (modulus approximately 1.3 GPa), and to various polyimide (modulus 2.5-10 GPa) and cellulose (modulus 15-25 GPa), among other possibilities.

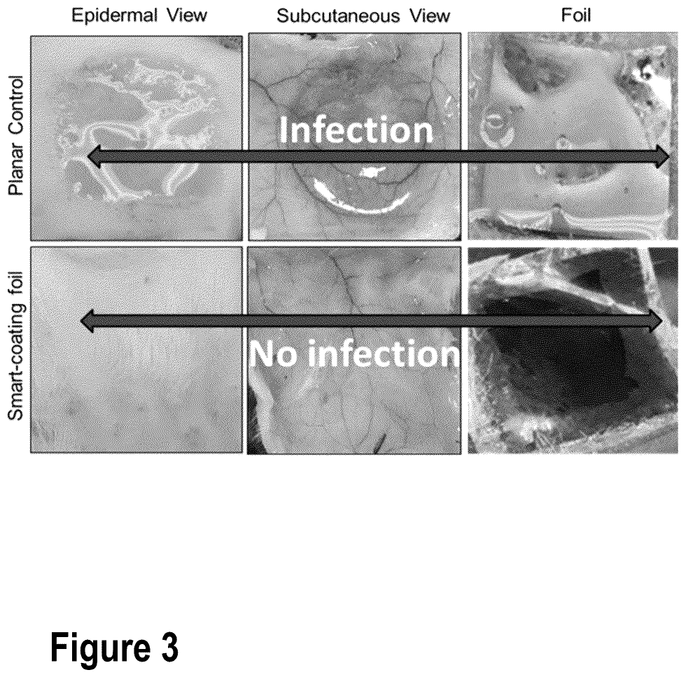

FIG. 3 illustrates optical images of the skin tissues around planar control and the biomimetic physical antimicrobial polymer foil inoculated with P. aeruginosa and normalized counts of S. aureus and P. aeruginosa, according to an example embodiment. Both the control and the foil were inoculated with five million colony forming units (CFUs) of P. aeruginosa. The optical images were obtained three days after inoculation with P. aeruginosa and are discussed further below.

The biomimetic properties of the nanopillars of the biomimetic physical antimicrobial polymer foils prevent infection in vivo. This property has been confirmed in a modified tape-stripping infection model of mice. Six- to nine-week-old CD-1 mice (cohorts of 6, equal ratio of males and females) were anesthetized by intraperitoneal injection of ketamine (80-100 mg/kg) and xylazine (10-12.5 mg/kg). The fur on the dorsal of mice was removed by shaving followed by exfoliating cream. Then, an area of approximately 2 cm² was tape-stripped with Tensoplast, an elastic adhesive bandage, 10 times in succession to disrupt the skin barrier by partial removal of the epidermal layer. The biomimetic physical antimicrobial polymer foils, along with planar controls, which had been sterilized and incubated for 12 hours at 37 degrees Celsius were innoculated with 5×10⁶ CFUs of S. aureus and 5×10⁶ CFUs of P. aeruginosa strain 27853105, in their liquid suspensions to mimic the surgical-site attachment of bacteria on implants. The treated foils were affixed onto the tape-stripped skin with surgical tape. Infected mice were monitored for 3 days, and euthanized by over-dosing with CO₂. Compared to the planar controls, the foils effectively prevent superficial infection as evident from the absence of pus and hemorrhage. The foil and the surrounding skin tissues were collected enbloc from all animals and vortexed for approximately 1 minute in 1 mL sterile saline to collect supernatant for CFU counting. The number of CFUs on the foils and skin in contact was many orders of magnitude, i.e., at least 1,000 times, lower than that of the control samples.

In other studies, the safety of the biomimetic physical antimicrobial polymer foils when interacting with human and mammalian cell, with no adverse inflammatory responses was demonstrated. Moreover, the biomimetic physical antimicrobial polymer foil retained their antimicrobial properties after 8 weeks of being implanted in in vivo environments.

In further studies, liquids containing various bacteria were applied to a biomimetic physical antimicrobial polymer foil. Next, a planar cover was applied to the liquid on the biomimetic physical antimicrobial polymer foil and the combination of foil and cover was allowed to incubate for between 1 and 12 hours. Subsequently, the concentrations of the bacteria were determined and compared with the original concentration of bacteria. These experiments revealed that the biomimetic physical antimicrobial polymer foils kill more than 99% of both gram-positive and gram-negative bacteria, including P. aeruginosa, S. aures, E. coli, Salmonella, and B. cereus.

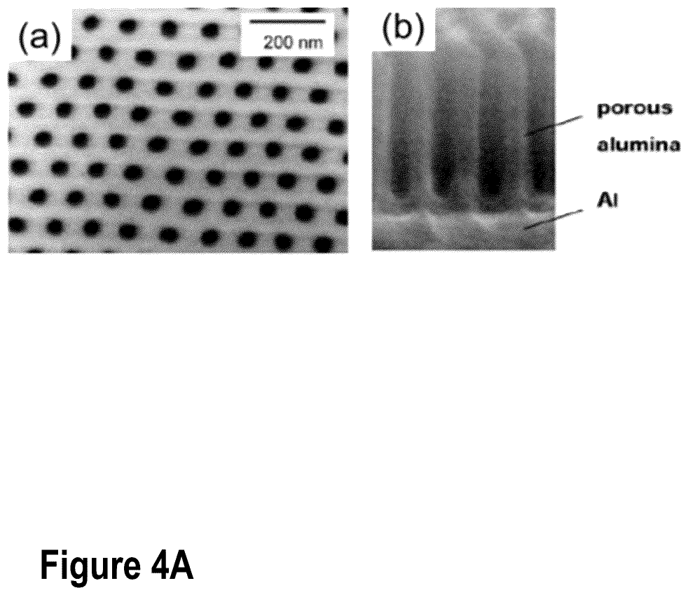

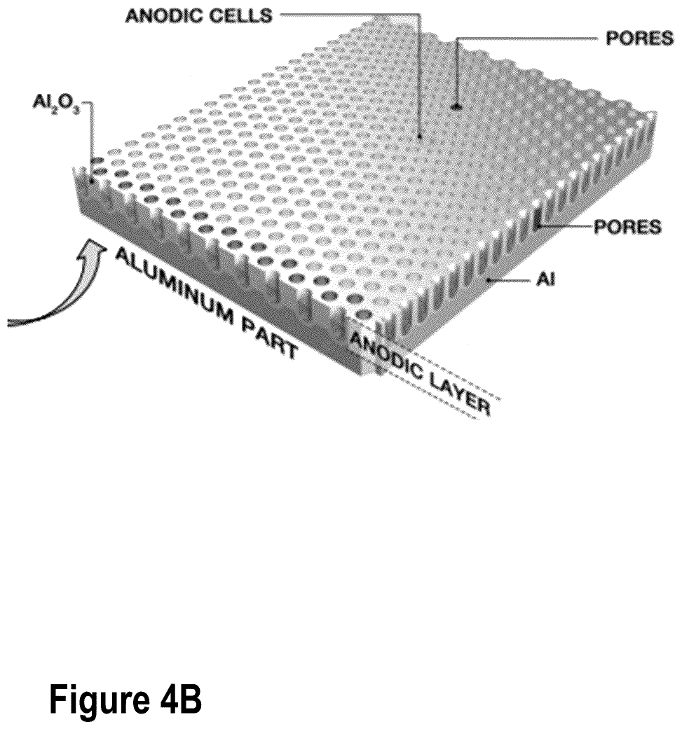

FIG. 4A illustrates SEM images of (a) cross-sectional and (b) top views of templates to create biomimetic physical antimicrobial polymer foils, according to an example embodiment. It indicates the approximate uniformity of the biomimetic physical antimicrobial polymer foils' pillar geometry, in terms of pitch, diameter, and height that can be achieved using such templates.

FIG. 4B illustrates a diagram of a template to create biomimetic physical antimicrobial polymer foils, according to an example embodiment. As shown in FIG. 4B, each of the plurality of pores 214 may lie within an anodic cell comprising Al₂O₃. The collection of anodic cells may form an anodic layer within the exposed surface 210 of the aluminum-containing layer 208.

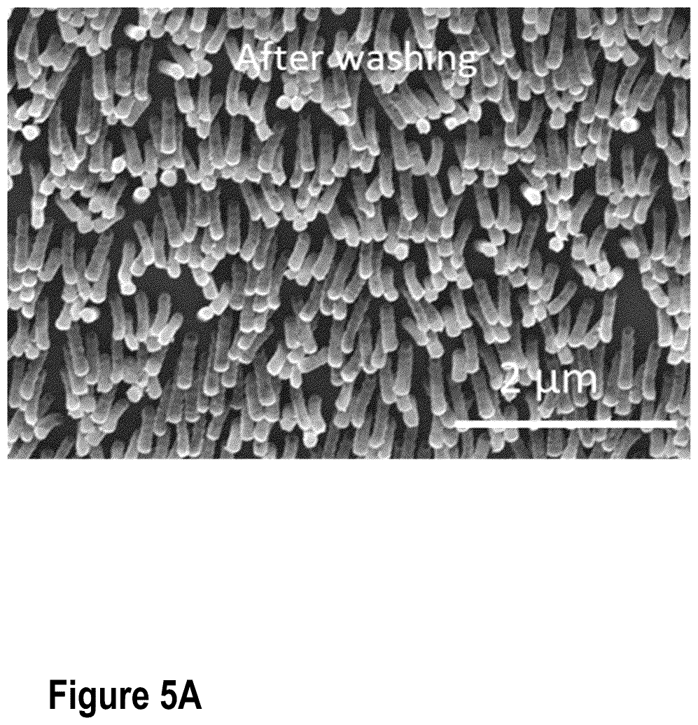

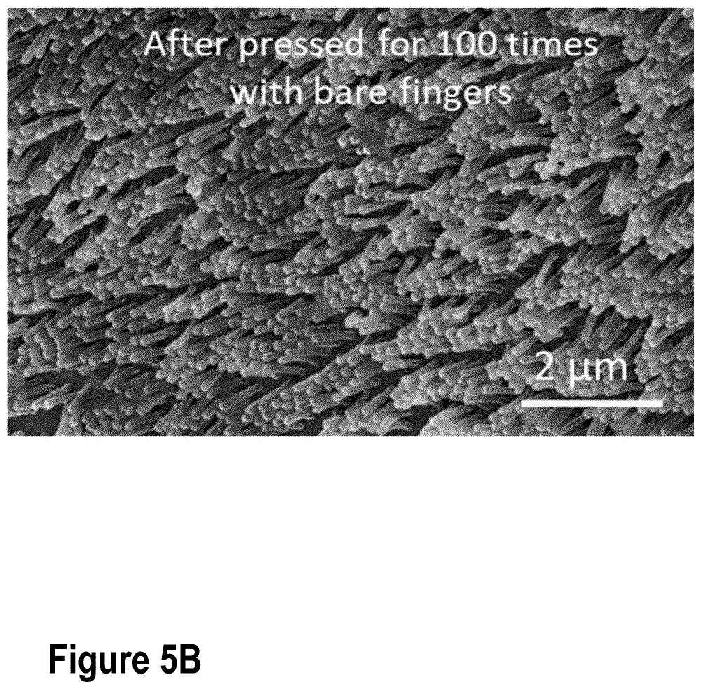

FIG. 5A illustrates a SEM image of a biomimetic physical antimicrobial polymer foil after washing, according to an example embodiment. The biomimetic physical antimicrobial polymer foil may show marginal, if any, damage following washing with water and/or alcohol.

FIG. 5B illustrates a SEM image of a biomimetic physical antimicrobial polymer foil after pressing with a finger, according to an example embodiment. The biomimetic physical antimicrobial polymer foil may show marginal, if any, damage after being pressed 100 times by a bare finger.

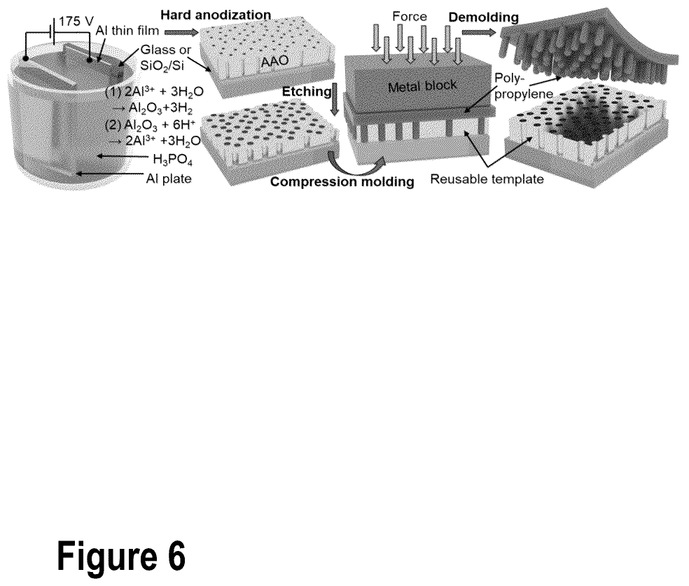

FIG. 6 illustrates a diagram of a method of manufacturing biomimetic physical antimicrobial polymer foils, according to an example embodiment. As shown in FIG. 6, the substrate 202 could comprise glass, silicone, silicone dioxide, or any combination thereof. The aluminum-containing layer 208 deposited on the substrate 202 could comprise an aluminum thin film. This combination of the substrate 202 and the aluminum-containing layer 208 could be anodized in the first bath 212 by applying a voltage of 175 volts, a process that could be referred to as “hard anodization.” The first bath 212 could comprise phosphoric acid. This anodization process could produce the plurality of pores 214. The plurality of pores 214 could be further etched, such as through immersing the exposed surface 210 in the first bath 212 or the second bath 216.

Further, as shown in FIG. 6, the polymer layer 222 could comprise polypropylene (PP). The aluminum-containing layer 208 and the polymer layer 222 could be heated and, while heating the polymer layer 222 and the aluminum-containing layer 208, the polymer layer 222 could be pressed onto the aluminum-containing layer 208. This pressing could be accomplished by means of a force applied to a material such as a metal block on the side of the polymer layer 222 opposite the face of the polymer layer 222 facing the aluminum-containing layer 208. Such a process of compression molding could be repeated multiple time using the same or a different polymer layer 222 and the same or a different aluminum-containing layer 208. Repeated performance of this process may produce biomimetic physical antimicrobial polymer foils with approximately consistent pillar pitch, diameter, and height. Further, different faces of the polymer layer 222 could be pressed onto the same aluminum-containing layer 208 or a different one.

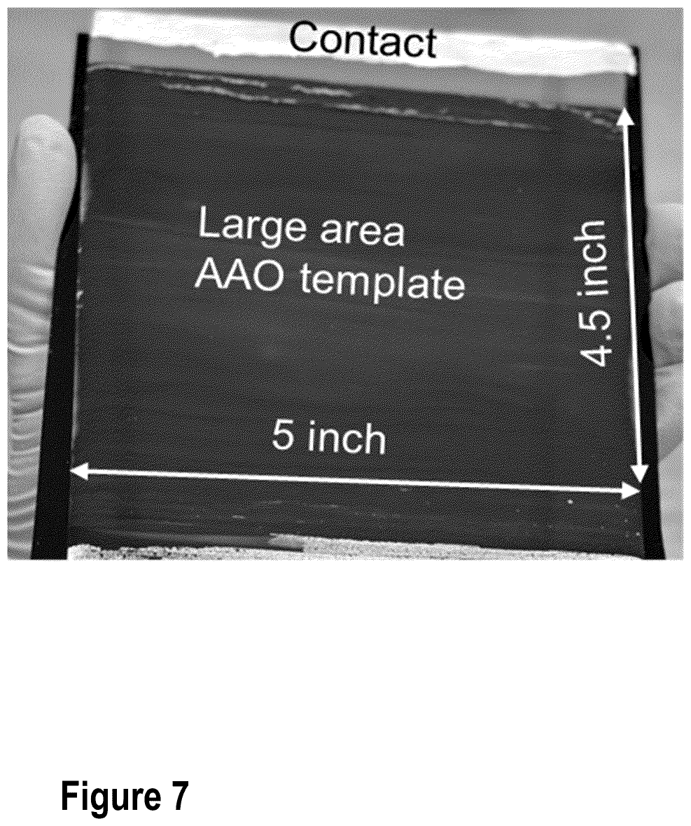

FIG. 7 illustrates an example template used to create biomimetic physical antimicrobial polymer foils, according to an example embodiment. Such a template could comprise the aluminum-containing layer 208. Such a template could also comprise the substrate 202 and the adhesion layer 206. This template could include a surface of at least 5 inches by 4.5 inches, enabling the production of biomimetic physical antimicrobial polymer foils that are of approximately the same size. It will be understood that biomimetic physical antimicrobial polymer foils with larger areas are possible and contemplated. For example, by utilizing roll-to-roll fabrication techniques, stamping, or other methods, large areas of biomimetic physical antimicrobial polymer foils may be realized.

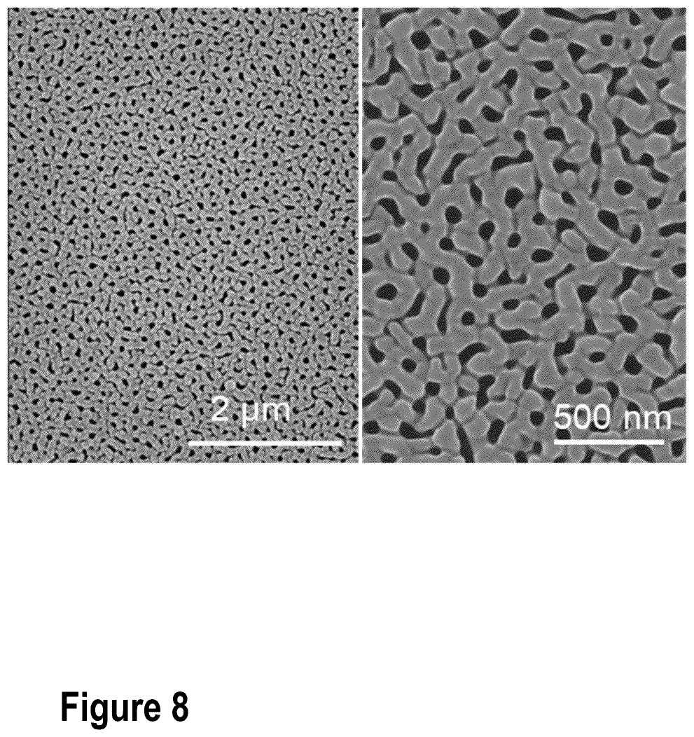

FIG. 8 illustrates SEM images of an example template used to create biomimetic physical antimicrobial polymer foils, according to an example embodiment. As shown in FIG. 8, it is possible to design the plurality of pores 214 such that, after the polymer layer 222 is separated from the aluminum-containing layer 208, the resulting pillars of the biomimetic physical antimicrobial polymer foils vary. For example, the pitch may change across the biomimetic physical antimicrobial polymer foils. The creation of biomimetic physical antimicrobial polymer foils with approximately uniform pitch may be easier. A benefit of creating biomimetic physical antimicrobial polymer foils with differing pitches could be broader bactericidal efficacy if different bacteria species have increased susceptibility to differing values of pitch. For example, a pitch of 200 nm could have increased bactericidal efficacy for species A whereas a pitch of 300 nm could have increased bactericidal efficacy for species B.

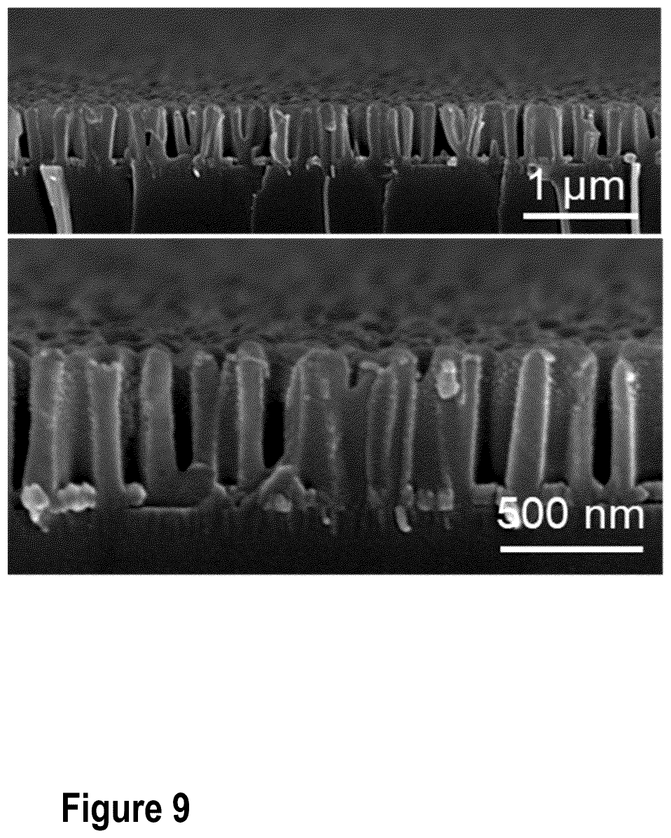

FIG. 9 illustrates cross-sectional view SEM images of a template used to create biomimetic physical antimicrobial polymer foils, according to an example embodiment. As shown in FIG. 9, it is possible to design the plurality of pores 214 such that, after the polymer layer 222 is separated from the aluminum-containing layer 208, the resulting pillars of the biomimetic physical antimicrobial polymer foils vary. For example, the pillar diameter and/or pillar height may change across the biomimetic physical antimicrobial polymer foils.

The creation of biomimetic physical antimicrobial polymer foils with approximately uniform pillar diameter and/or pillar height may be easier. A benefit of creating biomimetic physical antimicrobial polymer foils with differing pillar diameters and/or heights could be broader bactericidal efficacy if different bacteria species have increased susceptibility to differing values of pillar diameters and/or heights. For example, a pillar diameter of 50 nm and a height of 400 nm could have increased bactericidal efficacy for species A whereas a pillar diameter of 100 nm and a height of 800 nm has increased bactericidal efficacy for species B.

Further, combinations of pillar pitch, diameter, and height may be tuned to have increased bactericidal efficacy for certain harmful bacterial species, such as S. aures, while having reduced bactericidal efficacy for beneficial bacterial species, such as Lactobacillus rhamnosus.

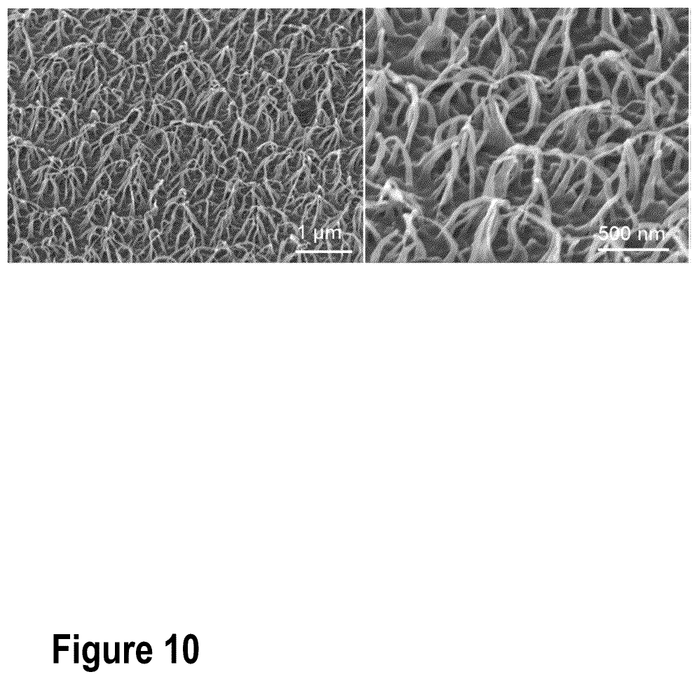

FIG. 10 illustrates top-view SEM images of the biomimetic physical antimicrobial polymer foils, according to an example embodiment. It indicates that an optimized pillar geometry should ensure both high bactericidal efficacy and structural stability.

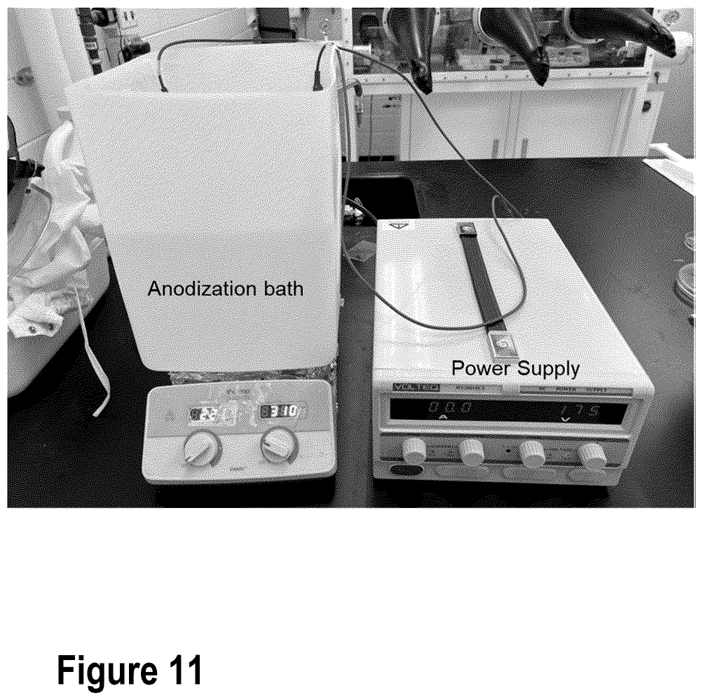

FIG. 11 illustrates part of an apparatus used to make the biomimetic physical antimicrobial polymer foils, according to an example embodiment. As shown in FIG. 11, the first bath 212 could be operationally connected to a power supply. This power supply could deliver a DC voltage of approximately 175 volts to the first bath 212. An alternating current (AC) voltage could be added to the DC voltage. The first bath 212 could be stirred at approximately 310 rotations per minute and could be heated to a temperature of 22 degrees Celsius. The temperature and the number of rotations per minute of the first bath 212 could be changed over time. Such changes could correspond to the changing voltage applied to the first bath 212.

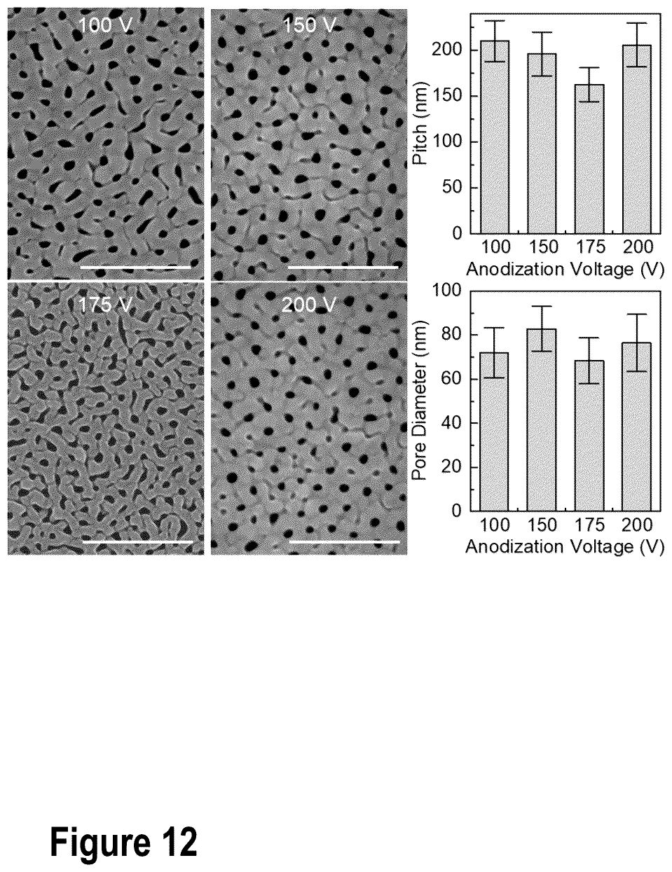

FIG. 12 illustrates top-view SEM images of templates used to create biomimetic physical antimicrobial polymer foils produced at different anodization voltages and resultant pitches and pore diameters of the plurality of pores 214, according to an example embodiment. Such templates could comprise the aluminum-containing layer 208. A DC voltage could be applied to the first bath 212 and/or the second bath 216. As shown in FIG. 12, across a range of voltages from 100 volts to 200 volts applied to the first bath 212, the pitch and pore diameter can be approximately consistent, for example at approximately 200 nm and 70 nm, respectively. It is possible for the pitch and pore diameter to change at voltages below 100 volts or above 200 volts. It is possible for the pitch and pore diameter to remain stable for a range of voltages beyond 100 volts to 200 volts.

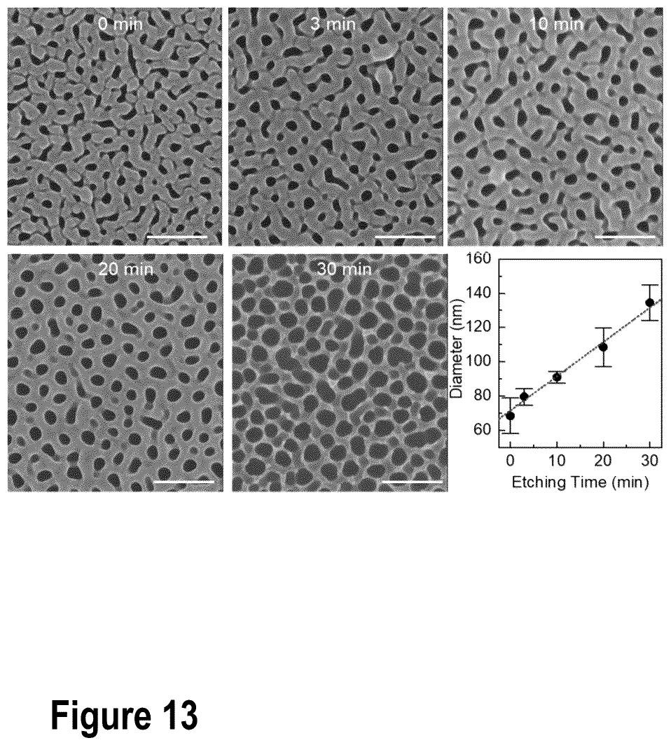

FIG. 13 illustrates top-view SEM images of templates used to create biomimetic physical antimicrobial polymer foils produced at different etching times and resultant pore diameters, according to an example embodiment. As shown in FIG. 13, the pore diameter of the plurality of pores 214 can increase as the length of time the exposed surface 210 is in the second bath 216 increases. The properties of the first bath 212 or second bath 216 can change over time. Such properties can include the pH, the quantity or type of surfactant, temperature, or pressure, among others.

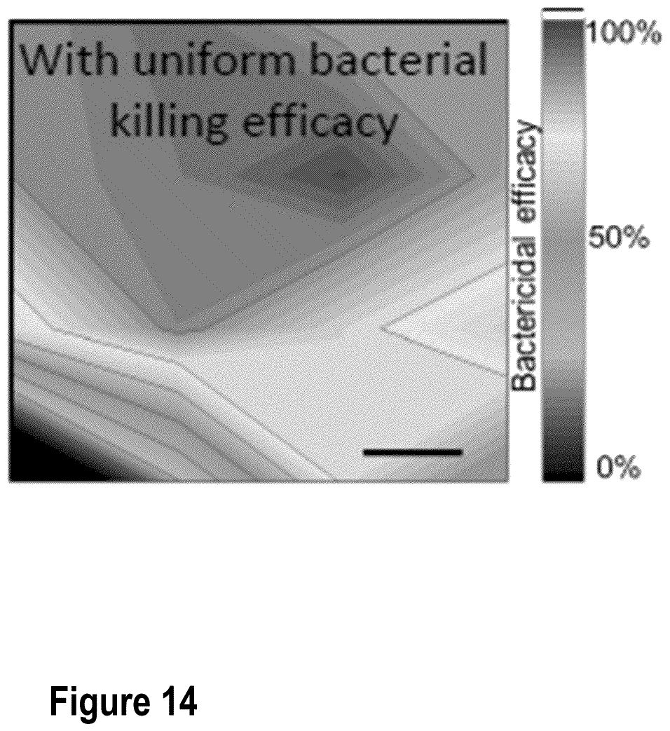

FIG. 14 illustrates a heat map of the bactericidal efficacy of the biomimetic physical antimicrobial polymer foil, according to an example embodiment. As shown in FIG. 14, the bactericidal efficacy of the biomimetic physical antimicrobial polymer foil could be approximately consistent across the foil or could change. A benefit of uniform bactericidal efficacy across a foil is providing uniform protection, such as for a large implant or food packaging. A situation in which non-uniform bactericidal efficacy could be desirable is when there are known regions inhabited by beneficial bacteria. In such scenarios, a foil could be designed to have lower bactericidal efficacy in the regions corresponding to the beneficial bacterial and a higher bactericidal efficacy elsewhere.

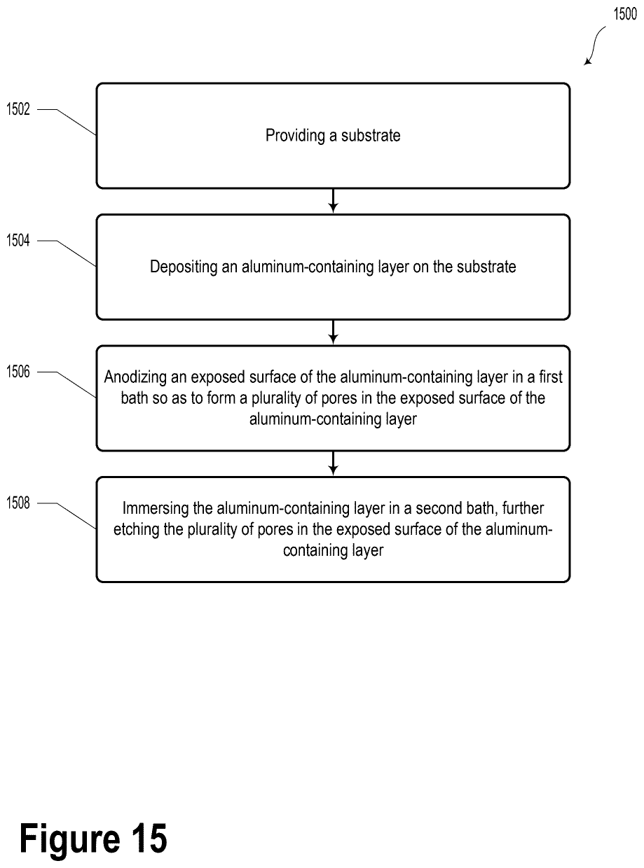

FIG. 15 illustrates a method 1500, according to an example embodiment. While the method 1500 illustrates several blocks of a method, it will be understood that fewer or more blocks or steps could be included. In such scenarios, at least some of the various blocks or steps may be carried out in a different order than of that presented herein. Furthermore, blocks or steps may be added, subtracted, transposed, and/or repeated.

Block 1502 includes providing a substrate (e.g., substrate 202).

Block 1504 includes depositing an aluminum-containing layer (e.g., aluminum-containing layer 208) on the substrate.

Block 1506 includes anodizing an exposed surface (e.g., exposed surface 210) of the aluminum-containing layer in a first bath (e.g., first bath 212) so as to form a plurality of pores (e.g., plurality of pores 214) in the exposed surface of the aluminum-containing layer.

Block 1508 includes immersing the exposed surface of the aluminum-containing layer in a second bath (e.g., second bath 216), further etching the plurality of pores in the exposed surface of the aluminum-containing layer.

In some example embodiments, the method 1500 also includes cleaning the exposed surface of the aluminum-containing layer. In some example embodiments, the method 1500 further includes, depositing a hydrophobicity-modifying layer (e.g., hydrophobicity-modifying layer 218) on the exposed surface of the aluminum-containing layer. In some example embodiments, the method 1500 can include depositing a polymer layer (e.g., polymer layer 222) on the hydrophobicity-modifying layer. In some example embodiments, the method 1500 may include heating the aluminum-containing layer and the polymer layer. In some example embodiments, the method 1500 further includes, while heating the aluminum-containing layer and the polymer layer, pressing the polymer layer onto the aluminum-containing layer, so as to cause a portion of the polymer layer to conformally fill the plurality of pores in the aluminum-containing layer. In some example embodiments, the method 1500 may include cooling the aluminum-containing layer and the polymer layer. In some example embodiments, the method 1500 can include separating the polymer layer from the aluminum-containing layer.

In some example embodiments, the polymer layer 222 in the form of liquid or gel phase precursors is deposited on the hydrophobicity-modifying layer. These precursors fill in the plurality of pores 214 in the aluminum-containing layer 208. In some example embodiments, this fill in is facilitated with the application of a low vacuum. The precursors are then solidified to form a solid-state thin foil. In some example embodiment, this solidification process is realized via crosslinking the precursors from monomers or oligomers into polymers via heating the aluminum-containing layer and the polymer layer. In some example embodiments, this solidification process is realized via removing the solvent from the precursor layer.

In some example embodiments, depositing the hydrophobicity-modifying layer also includes controllably adjusting an adhesive force between the aluminum-containing layer and the polymer layer.

In some example embodiments, depositing the hydrophobicity-modifying layer includes exposing the exposed surface of the aluminum-containing layer to trichlorosilane vapor in a desiccator chamber (e.g., desiccator chamber 220).

In some example embodiments, depositing the hydrophobicity-modifying layer includes exposing the exposed surface of the aluminum-containing layer to oxygen plasma in a vacuum chamber.

In some example embodiments, the polymer layer could include at least one of: polypropylene (PP), polyethylene (PE), polyvinyl chloride (PVC), polyurethane (PU), silicone rubber, ethylene propylene diene monomer (EPDM), thermoplastic elastomers (TPEs), thermoplastic polyurethane (TPU), polyvinylidene fluoride (PVDF), cellulose, or lignin.

In some example embodiments, the anodizing and immersing steps etch the plurality of pores into the exposed surface of the aluminum-containing layer. In some examples, the pores have diameters of approximately 100 nanometers, pitches between 200 and 300 nanometers, and depths of between 300 and 800 nanometers.

In some example embodiments, anodizing the exposed surface of the aluminum-containing layer includes carrying out an anodization process in the first bath. In such scenarios, the first bath could include a 5% by volume phosphoric acid solution. Additionally or alternatively, immersing the aluminum-containing layer could include carrying out an etch process in the second bath. In some embodiments, the second bath could include a 10% by volume phosphoric acid solution.

In some example embodiments, depositing the aluminum-containing layer includes depositing an aluminum layer with a thickness of 150-400 nanometers.

In some example embodiments, depositing the aluminum-containing layer is performed with a metal sputtering deposition process.

In some example embodiments, anodizing the exposed surface of the aluminum-containing layer in the first bath includes applying a voltage of approximately 175 volts and stirring the first bath at approximately 300 rotations per minute.

In some example embodiments, method 1500 may also include depositing an adhesion layer on the substrate. In such scenarios, the adhesion layer could include approximately 1 nanometer thick titanium. It will be understood that other materials and thicknesses for the adhesion layer are possible within the scope of the present disclosure.

### IV. Cellulose Films with Biomimetic Mechano-Bactericidal Nanostructures

Some example embodiments of the methods and apparatuses described herein may provide a sustainable, biodegradable, and biosafe biomaterial for food packaging. Such apparatuses and constituent materials may provide similar mechanical properties to polyimide and additionally provide optical transparency to enable visual product inspection.

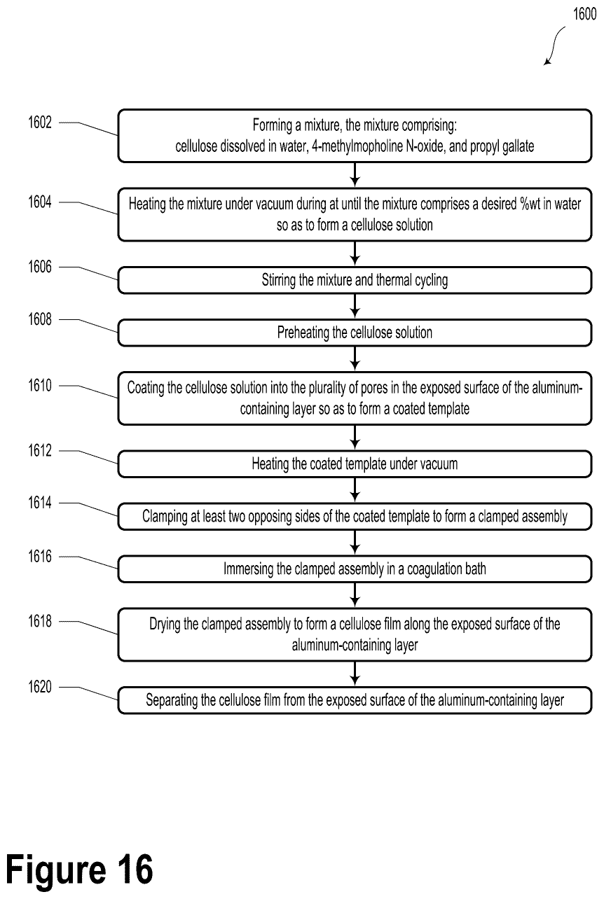

FIG. 16 illustrates a method 1600, according to an example embodiment. While the method 1600 illustrates several blocks of a method, it will be understood that fewer or more blocks or steps could be included. In such scenarios, at least some of the various blocks or steps may be carried out in a different order than of that presented herein. Furthermore, blocks or steps may be added, subtracted, transposed, and/or repeated.

In some examples, method 1600 could include steps or blocks that could be similar or identical to those described in relation to method 1500 and FIG. 15. In other words, method 1600 could include preparing an aluminum-containing layer that may serve as a template for forming polymer layers (e.g., polymer layer 222). Yet further, in some embodiments, method 1600 may provide templated cellulose films having nanopillar structures.

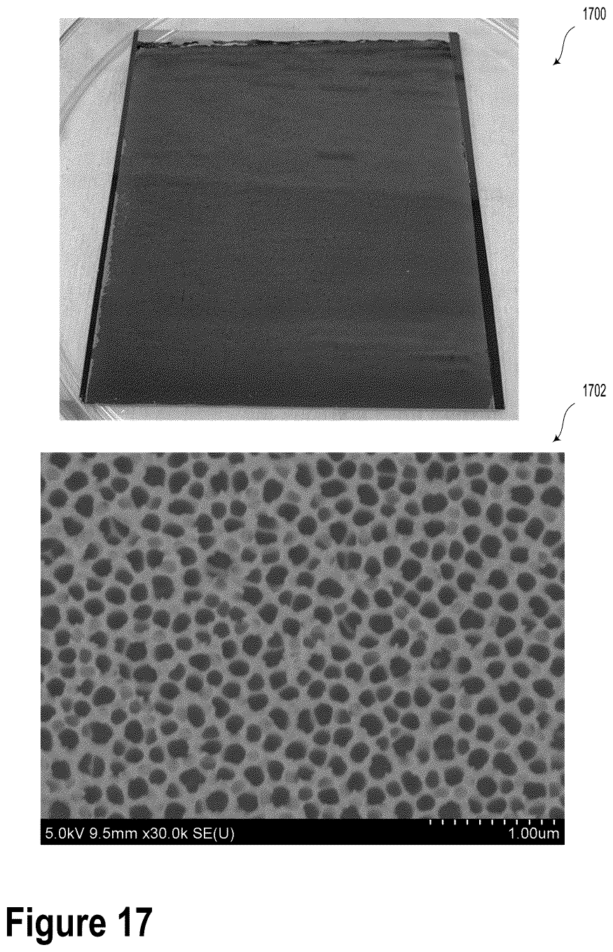

FIG. 17 illustrates a camera image 1700 a template and a SEM image 1702 of a template, according to an example embodiment. In such scenarios, the process for forming the template may include sputtering 1 nm Ti followed by 400 nm Al onto a Si wafer with a 90 nm SiO₂ layer. In some embodiments, silver paste is applied to the top Al strip to improve electrical contact with the power supply. In some examples, two Al-free strips on both sides of the template are provided to accommodate volume expansion during aluminum oxide formation, which may prevent delamination. In some embodiments, the Al film is gradually immersed into a 5% H₃PO₄ solution to form anodized aluminum oxide (AAO).

The process may also include connecting the Al film to an anode of the power supply and connecting the cathode of the power supply to an Al foil, which serves as a counter electrode. In various examples, the anodization voltage applied between anode and cathode could be approximately 180 V. It will be understood that other voltages are possible and contemplated.

After anodization, the template may be immersed in 10% H₃PO₄ to enlarge the pore size. In such scenarios, the hole size could be about ˜150 nm, the pitch ˜200 nm, and the depth ˜800 nm. It will be understood that hole dimensions and spacing could vary based on the desired thin film material. In some examples, cellulose thin films and corresponding nanopillar structures may experience shrinkage on the order of 40-60%. Accordingly, the hole size and depth of a template for use with cellulose thin films may be greater than in comparison for thin film materials that experience lower amounts of shrinkage.

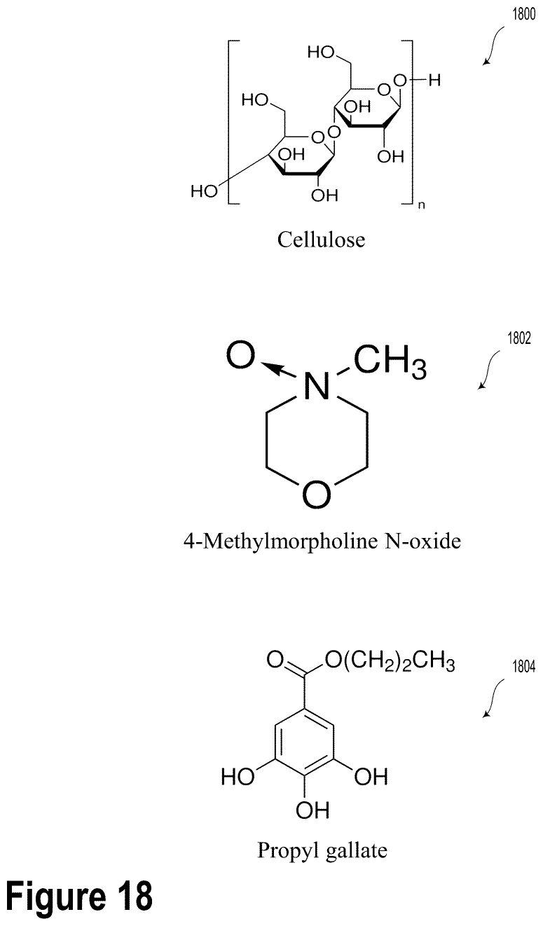

FIG. 18 illustrates various chemical structures, according to an example embodiment. The chemical structures include cellulose 1800, 4-methylmorpholine N-oxide 1802, and propyl gallate 1804. Cellulose 1800 is a polysaccharide chain forming a linear polymer of glucose. In some applications, 4-methylmorpholine N-oxide 1802 may be used as a solvent in organic synthesis and to dissolve cellulose. Propyl gallate 1804 includes a benzene ring substituted with three hydroxyl groups (a galloyl group) and an ester linkage to a propyl group.

The steps or blocks of method 1600 are now provided.

Block 1602 includes forming a mixture. The mixture includes cellulose dissolved in water, 4-methylmopholine N-oxide, and propyl gallate. In some embodiments, the cellulose solution may be a 10 wt % cellulose solution in water. Additionally or alternatively, the 4-methylmopholine N-oxide could be a solution of 89.5 wt % 4-Methylmorpholine N-oxide (50% in H₂O). In various examples, the propyl gallate could be 0.5 wt % propyl gallate (antioxidant). In some embodiments, all materials may be mixed in a vial.

Block 1604 includes heating the mixture under vacuum until the mixture comprises a desired % wt in water so as to form a cellulose solution. As an example, the vial may be placed in a vacuum oven at 100° C. under vacuum (e.g., 100 mT) to evaporate water until the remaining water content is approximately 15 wt % of the original total weight. It will be understood that other wt % of cellulose/water are possible and contemplated.

Block 1606 includes stirring the solution overnight at ˜100° C. followed by three thermal cycles to ensure improved or complete dissolution and uniformity.

Block 1608 includes preheating the cellulose solution. In such scenarios, the 10 wt % cellulose solution could be heated to ˜100° C.

Block 1610 includes coating the cellulose solution into the plurality of pores in the exposed surface of the aluminum-containing layer so as to form a coated template. In such scenarios, the solution may be applied to the AAO template, ensuring the entire surface is covered. In some examples, the solution may be spin coated at 1000 rpm with a ramp rate of 1000 rpm/s for 30 seconds. In such scenarios, the spin speed may be adjusted to control the final film thickness, ensuring the film remains thin and flexible.

It will be understood that other thin film deposition and/or solution application techniques are possible and contemplated, including slit-casting (or slot die coating) or doctor blading (or knife coating).

Block 1612 includes heating the coated template under vacuum. In such scenarios, the coated template could be heated in to a vacuum oven at ˜100° C. under vacuum for approximately 10 minutes.

Block 1614 includes clamping at least two opposing sides of the coated template to form a clamped assembly. In an example embodiment, clips and/or other types of clamps may be used to secure all four edges to the template/substrate during the solvent removal process.

Block 1616 includes immersing the clamped assembly in a coagulation bath. In such scenarios, the clamped assembly may be immersed into a coagulation bath of deionized water for 1 hour.

Block 1618 includes drying the clamped assembly to form a cellulose film along the exposed surface of the aluminum-containing layer. Once the clamped assembly is removed from the bath, it can be air dried in a fume hood with clips/clamps still attached.

Block 1620 includes separating the cellulose film from the exposed surface of the aluminum-containing layer. In such scenarios, once the clamped assembly has dried, the clips may be removed. Subsequently, the cellulose film may be peeled or otherwise separated from the AAO template.

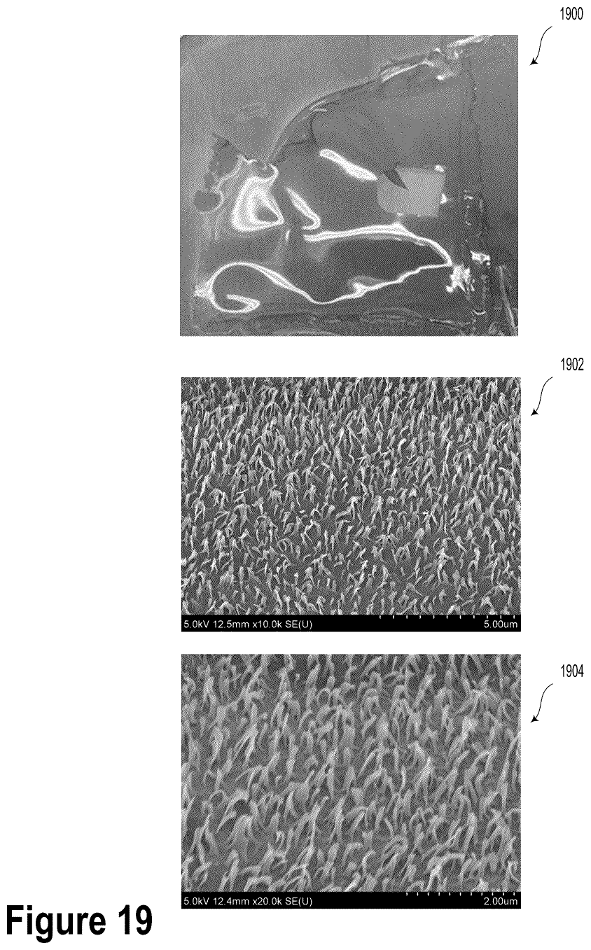

FIG. 19 illustrates various views of a cellulose film, according to an example embodiment. The views of the cellulose film include a camera image 1900, a first SEM image 1902 and a second SEM image 1904 of the cellulose film.

### V. Conclusion

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A method, comprising:
providing a substrate;
depositing an aluminum-containing layer on the substrate;
anodizing an exposed surface of the aluminum-containing layer in a first bath so as to form a plurality of pores in the exposed surface of the aluminum-containing layer; and
immersing the exposed surface of the aluminum-containing layer in a second bath, further etching the plurality of pores in the exposed surface of the aluminum-containing layer.

2. The method of claim 1, further comprising:
cleaning the exposed surface of the aluminum-containing layer;
depositing a hydrophobicity-modifying layer on the exposed surface of the aluminum-containing layer;
depositing a polymer layer on the hydrophobicity-modifying layer;
heating the aluminum-containing layer and the polymer layer;
while heating the aluminum-containing layer and the polymer layer, pressing the polymer layer onto the aluminum-containing layer, so as to cause a portion of the polymer layer to conformally fill the plurality of pores in the aluminum-containing layer;
cooling the aluminum-containing layer and the polymer layer; and
separating the polymer layer from the aluminum-containing layer.

3. The method of claim 2, wherein depositing the hydrophobicity-modifying layer further comprises controllably adjusting an adhesive force between the aluminum-containing layer and the polymer layer.

4. The method of claim 2, wherein depositing the hydrophobicity-modifying layer comprises exposing the exposed surface of the aluminum-containing layer to trichlorosilane vapor in a desiccator chamber.

5. The method of claim 2, wherein depositing the hydrophobicity-modifying layer comprises exposing the exposed surface of the aluminum-containing layer to oxygen plasma in a vacuum chamber.

6. The method of claim 2, wherein the polymer layer comprises at least one of: polypropylene (PP), polyethylene (PE), polyvinyl chloride (PVC), polyurethane (PU), silicone rubber, ethylene propylene diene monomer (EPDM), thermoplastic elastomers (TPEs), thermoplastic polyurethane (TPU), polyvinylidene fluoride (PVDF), cellulose, or lignin.

7. The method of claim 1, wherein the anodizing and immersing steps etch the plurality of pores into the exposed surface of the aluminum-containing layer, wherein the pores have diameters of approximately 100 nanometers, pitches between 200 and 300 nanometers, and depths of between 300 and 800 nanometers.

8. The method of claim 1, wherein anodizing the exposed surface of the aluminum-containing layer in the first bath comprises applying a voltage of approximately 175 volts and stirring the first bath at approximately 300 rotations per minute, wherein the first bath comprises a 5% by volume phosphoric acid solution, and wherein immersing the aluminum-containing layer comprises:
carrying out an etch process in the second bath, wherein the second bath comprises a 10% by volume phosphoric acid solution.

9. The method of claim 1, wherein depositing the aluminum-containing layer comprises depositing an aluminum layer with a thickness of 150-400 nanometers and wherein depositing the aluminum-containing layer is performed with a metal sputtering deposition process.

10. The method of claim 1, further comprising:
depositing an adhesion layer on the substrate, wherein the adhesion layer comprises approximately 1 nanometer thick titanium.

11. The method of claim 2, further comprising:
forming a mixture, the mixture comprising:
cellulose dissolved in water;
4-methylmopholine N-oxide; and
propyl gallate;
heating the mixture under vacuum until the mixture comprises a desired % wt in water so as to form a cellulose solution;
stirring the mixture and performing thermal cycles.

12. The method of claim 11, further comprising:
preheating the cellulose solution;
coating the cellulose solution into the plurality of pores in the exposed surface of the aluminum-containing layer so as to form a coated template;
heating the coated template under vacuum;
clamping at least two opposing sides of the coated template to form a clamped assembly;
immersing the clamped assembly in a coagulation bath;
drying the clamped assembly to form a cellulose film along the exposed surface of the aluminum-containing layer; and
separating the cellulose film from the exposed surface of the aluminum-containing layer.

13. An apparatus comprising:
an aluminum-containing deposition system, wherein the aluminum-containing deposition system is configured to deposit an aluminum-containing layer on a substrate;
a first bath, wherein the first bath is configured to anodically etch a plurality of pores in an exposed surface of the aluminum-containing layer; and
a second bath, wherein the second bath is configured to further etch the plurality of pores.

14. The apparatus of claim 13, further comprising:
a desiccator chamber, wherein the desiccator chamber is configured to deposit a hydrophobicity-modifying layer on the exposed surface of the aluminum-containing layer, wherein the hydrophobicity-modifying layer comprises silicon dioxide.

15. The apparatus of claim 14, further comprises:
a polymer deposition apparatus, wherein the polymer deposition apparatus is configured to deposit a polymer layer on the hydrophobicity-modifying layer, heat the aluminum-containing layer and the polymer layer, and press the polymer layer onto the aluminum-containing layer so as to cause a portion of the polymer layer to conformally fill the plurality of pores in the aluminum-containing layer.

16. The apparatus of claim 15, further comprising:
a controller having at least one processor and a memory, wherein the at least one processor executes program instructions stored in the memory so as to carry out operations, the operations comprising:
controlling at least one of a voltage applied to the first bath, a temperature of the polymer deposition apparatus, a rate of rotation of a stirrer in the first bath, a pressure within the polymer deposition apparatus, a force at which to press the polymer layer onto the aluminum-containing layer, a pressure within the desiccator chamber, or a pressure within the aluminum-containing deposition system.

17. The apparatus of claim 13, wherein the first bath comprises a 5% by volume phosphoric acid solution and wherein the second bath comprises a 10% by volume phosphoric acid solution.

18. The apparatus of claim 13, wherein the first bath and the second bath comprise respective phosphoric acid solutions having a same phosphoric acid formulation by volume.

19. The apparatus of claim 13, wherein the plurality of pores in the exposed surface of the aluminum-containing layer have diameters of approximately 100 nanometers, pitches between 200 and 300 nanometers, and depths of between 300 and 800 nanometers.

20. A method comprising:
applying an adhesion layer to a substrate, wherein the adhesion layer comprises 1 nanometer thick titanium, wherein the substrate comprises silicon;
depositing an aluminum-containing layer on the adhesion layer, wherein the aluminum-containing layer comprises a thickness of 150-400 nanometers, and wherein depositing the aluminum-containing layer is performed with a metal sputtering deposition process;
anodizing an exposed surface of the aluminum-containing layer in a first bath so as to form a plurality of pores in the exposed surface of the aluminum-containing layer, wherein the first bath comprises a 5% by volume phosphoric acid solution, and wherein the anodizing comprises applying a voltage of approximately 175 volts and stirring the first bath at approximately 300 rotations per minute;
immersing the exposed surface of the aluminum-containing layer in a second bath, further etching the plurality of pores in the exposed surface of the aluminum-containing layer, wherein the pores have diameters of approximately 100 nanometers, pitches between 200 and 300 nanometers, and depths of between 300 and 800 nanometers, and wherein the second bath comprises a 10% by volume phosphoric acid solution;
cleaning the exposed surface of the aluminum-containing layer;
depositing a hydrophobicity-modifying layer on the exposed surface of the aluminum-containing layer, wherein depositing the hydrophobicity-modifying layer comprises exposing the exposed surface of the aluminum-containing layer to trichlorosilane vapor in a desiccator;
depositing a polymer layer on the hydrophobicity-modifying layer, wherein the polymer layer comprises polypropylene (PP);
heating the aluminum-containing layer and the polymer layer together to a temperature of approximately 200 degrees Celsius;
while heating the aluminum-containing layer and the polymer layer, pressing the polymer layer onto the aluminum-containing layer, so as to cause a portion of the polymer layer to conformally fill the plurality of pores in the aluminum-containing layer; and
separating the polymer layer from the aluminum-containing layer.
